(19) United States
(12) Patent Application Publication
(10) Pub. No.: US 2026/0123190 A1
(43) Pub. Date: Apr. 30, 2026

(54) DISPLAY PANEL AND DISPLAY DEVICE

(71) Applicant: HKC CORPORATION LIMITED, Shenzhen (CN)

(72) Inventors: Zhonglin CAO, Shenzhen (CN); Tien-Chun HUANG, Taiwan (CN); Chuan WU, Shenzhen (CN); Wenyu YI, Shenzhen (CN); Dongmei WEI, Shenzhen (CN); Yao LI, Shenzhen (CN); Jie CHEN, Shenzhen (CN); Lidan YE, Shenzhen (CN)

(73) Assignee: HKC CORPORATION LIMITED, Shenzhen (CN)

(21) Appl. No.: 19/369,229

(22) Filed: Oct. 26, 2025

(30) Foreign Application Priority Data
Oct. 31, 2024 (CN) 202411550180.0

(51) Int. Cl. H10K 59/122; H10K 59/80

(52) U.S. Cl. CPC H10K 59/122; H10K 59/873

(57) ABSTRACT

The present application provides a display panel and a display device. The driving circuit backplane and the light-emitting unit carrier are bonded through a bonding component, the bonding component passes through the second substrate. One side of the bonding component is connected to the anode film layer, and an other side of the bonding component is bonded to the driving circuit layer, making the driving circuit layer and the anode film layer electrically connected. After the driving circuit backplane and the light-emitting unit carrier are bonded, a gap is defined between the second substrate and the first substrate. The encapsulation layer is arranged on the first substrate and extends the encapsulation layer to the gap.

### CROSS-REFERENCE TO RELATED APPLICATIONS

The present disclosure claims priority of Chinese Patent Application No. 202411550180.0, entitled “DISPLAY PANEL AND DISPLAY DEVICE”, filed on Oct. 31, 2024, the contents of which are hereby incorporated by reference.

### TECHNICAL FIELD

The present disclosure relates to the field of display technologies, and in particular, to a display panel and a display device.

### BACKGROUND

In the field of display, a silicon-based organic light emitting diode (OLED) panel formed by bonding a silicon-based substrate and a glass substrate is gradually becoming a low-cost solution for the silicon-based OLED due to low manufacturing difficulty. However, there is often a risk of water vapor intrusion at a bonding interface between the silicon-based and the glass substrate, thereby leading to corrosion and failure inside the display panel.

### SUMMARY

The present disclosure provides a display panel. The display panel includes: a driving circuit backplane, including a first substrate and a driving circuit layer arranged on the first substrate; a light-emitting unit carrier, including a second substrate, a pixel defining layer, an organic light emitting diode device, and a bonding component; where the pixel defining layer is arranged on the second substrate, and the pixel defining layer is spaced apart to form a pixel region; the organic light emitting diode device includes an anode film layer, a light-emitting layer, and a cathode film layer formed in sequence from a side close to the driving circuit backplane to a side facing away from the driving circuit backplane; the anode film layer, the light-emitting layer, and the cathode film layer are arranged on the pixel region, and on a side of the pixel region facing away from the second substrate, the cathode film layer covers both the pixel defining layer and the pixel region; the bonding component passes through the second substrate, one side of the bonding component is electrically connected to the anode film layer, and an other side of the bonding component is bonded to the driving circuit layer; a gap, defined between the second substrate and the first substrate, where a length of the second substrate is less than a length of the first substrate; an end of the first substrate is close to an end of the second substrate to define a step surface, and the step surface communicates with the gap; an encapsulation layer, arranged at least on the first substrate and extending to the step surface to encapsulate the gap between the first substrate and the second substrate.

The present disclosure provides a display panel. The display panel includes: a driving circuit backplane, including a first substrate and a driving circuit layer arranged on the first substrate; a light-emitting unit carrier, including a second substrate, a pixel defining layer, an organic light emitting diode device, and a bonding component; where the pixel defining layer is arranged on the second substrate, and the pixel defining layer defines a pixel region; the organic light emitting diode device includes an anode film layer, a light-emitting layer, and a cathode film layer formed in sequence from a side close to the driving circuit backplane to a side facing away from the driving circuit backplane; the anode film layer, the light-emitting layer, and the cathode film layer are arranged on the pixel region, and on a side of the pixel region facing away from the second substrate, the cathode film layer covers both the pixel defining layer and the pixel region; the bonding component passes through the second substrate, one side of the bonding component is electrically connected to the anode film layer, and an other side of the bonding component is bonded to the driving circuit layer; a gap, between the second substrate and the first substrate, where a length of the second substrate is less than a length of the first substrate; an end of the first substrate is close to an end of the second substrate to define a step surface, and the step surface communicates with the gap; and a drying component, where the drying component is arranged on the step surface, and is close to the gap; or an accommodation groove, communicating with the gap, is defined on at least one of the first substrate and the second substrate; an opening of the accommodation groove faces the step surface, and the drying component is arranged in the accommodation groove

The present disclosure also provides a display device including a display panel. The display panel includes: a driving circuit backplane, including a first substrate and a driving circuit layer arranged on the first substrate; a light-emitting unit carrier, including a second substrate, a pixel defining layer, an organic light emitting diode device, and a bonding component; where the pixel defining layer is arranged on the second substrate, and the pixel defining layer is spaced apart to form a pixel region; the organic light emitting diode device includes an anode film layer, a light-emitting layer, and a cathode film layer formed in sequence from a side close to the driving circuit backplane to a side facing away from the driving circuit backplane; the anode film layer, the light-emitting layer, and the cathode film layer are arranged on the pixel region, and on a side of the pixel region facing away from the second substrate, the cathode film layer covers both the pixel defining layer and the pixel region; the bonding component passes through the second substrate, one side of the bonding component is electrically connected to the anode film layer, and an other side of the bonding component is bonded to the driving circuit layer; a gap, defined between the second substrate and the first substrate, where a length of the second substrate is less than a length of the first substrate; an end of the first substrate is close to an end of the second substrate to define a step surface, and the step surface communicates with the gap; an encapsulation layer, arranged at least on the first substrate and extending to the step surface to encapsulate the gap between the first substrate and the second substrate.

It should be understood that the above general description and the subsequent detailed description are only exemplary and explanatory, and should not limit the scope of the present disclosure.

### BRIEF DESCRIPTION OF THE DRAWINGS

The accompanying drawings are incorporated into the specification and form a portion of the specification, illustrating embodiments in accordance with the present disclosure and used together with the specification to explain the principle of the present disclosure. Apparently, the drawings described below are only for illustration, but not for limitation. One skilled in the art may obtain other drawings based on these drawings, without making any inventive work.

FIG. 1 is a first structural schematic view of a display panel provided by some embodiments of the present disclosure, where an encapsulation layer includes a first packaging part.

FIG. 2 is a second structural schematic view of a display panel provided by some embodiments of the present disclosure, where an encapsulation layer includes a first packaging part and a second packaging part, and the first packaging part extends on a step surface.

FIG. 3 is a third structural schematic view of a display panel provided by some embodiments of the present disclosure, where an encapsulation layer includes a first packaging part and a second packaging part, and the first packaging part extends to a third plane.

FIG. 4 is a fourth structural schematic view of a display panel provided by some embodiments of the present disclosure, where an encapsulation layer includes a first packaging part, a second packaging part, and a third packaging part.

FIG. 5 is a first structural schematic view of a display panel provided with a desiccant provided by some embodiments of the present disclosure.

FIG. 6 is a second structural schematic view of a display panel provided with a desiccant provided by some embodiments of the present disclosure.

FIG. 7 is a third structural schematic view of a display panel provided with a desiccant provided by some embodiments of the present disclosure.

FIG. 8 is a structural schematic view of a driving circuit backplane provided by some embodiments of the present disclosure.

FIG. 9 is a structural schematic view of a display device provided by some embodiments of the present disclosure.

Reference numerals are illustrated as follows:

100, display panel; 10, driving circuit backplane; 11, first substrate; 111, third plane; 20, light-emitting unit carrier; 21, second substrate; 211, light-emitting region; 212, non-light-emitting region; 213, first plane; 214, second plane; 22, pixel defining layer; 221, pixel region; 23, organic light-emitting diode device; 231, anode film layer; 232, light-emitting layer; 233, cathode membrane layer; 24, bonding component; D, gap; 30, step surface; 40, encapsulation layer; 41, first packaging part; 42, second packaging part; 43, third packaging part; 50, drying component; 51, first drying piece; 52, second drying piece; 60, accommodation groove; 61, first accommodation groove; 62, second accommodation groove; 1, display device.

### DETAILED DESCRIPTION OF THE PREFERRED EMBODIMENTS

Embodiments will now be described more fully with reference to the drawings. However, the exemplary embodiments can be implemented in a variety of forms and should not be construed as being limited to the examples set forth herein. On the contrary, these exemplary embodiments are provided to make the present disclosure more comprehensive and complete, and fully convey the concept of the exemplary embodiments to those skilled in the art.

In addition, described features, structures or characteristics may be combined in one or more embodiments in any suitable manner. In the following description, many specific details are provided to give a full understanding of the embodiments of the present disclosure. However, those skilled in the art will realize that the technical scheme of the present disclosure can be practiced without omitting one or more of the specific details, or by using other methods, components, apparatuses, steps, and the like. In other cases, well-known structures, methods, apparatuses, implementations, or operations are not shown or described in detail to avoid confusing aspects of the present disclosure.

The present disclosure will be further described in detail with reference to the accompanying drawings and specific embodiments. It should be noted that the technical features involved in the various embodiments of the present disclosure described below can be combined with each other as long as they do not conflict with each other. The embodiments described below with reference to the accompanying drawings are exemplary and intended to explain the present disclosure, and should not be construed as limiting the present disclosure.

It should be noted that the terms “multiple” or “a plurality of” refer to two or more, such as two, three, etc., unless otherwise expressly and specifically defined. The term “and/or” describes the association relationship of the associated objects, indicating that there can be three relationships. For example, A and/or B, can indicate the presence of A alone, B alone and both A and B at the same time. The symbol “/” generally indicates that the front and rear associated objects are an “or” relationship.

In the field of display, a silicon-based organic light emitting diode (OLED) panel formed by bonding a silicon-based substrate and a glass substrate is gradually becoming a low-cost solution for the silicon-based OLED due to low manufacturing difficulty. However, there is often a risk of water vapor intrusion at a bonding interface between the silicon-based and the glass substrate, thereby leading to corrosion and failure inside the display panel.

In order to solve the above technical problems, referring to FIG. 1 to FIG. 4, the present disclosure provides a display panel 100. The display panel 100 includes a driving circuit backplane 10, a light-emitting unit carrier 20, and an encapsulation layer 40. The driving circuit backplane 10 includes a first substrate 11 and a driving circuit layer (shown in FIG. 8) arranged on the first substrate 11. The light-emitting unit carrier 20 includes a second substrate 21, a pixel defining layer 22, an organic light-emitting diode device 23, and a bonding component 24. The pixel defining layer 22 is arranged on the second substrate 21, and the pixel defining layer 22 defines a pixel region 221. Alternatively, the pixel defining layer 22 defines a plurality of pixel regions 221, and the plurality of pixel regions 221 are spaced apart from each other. The organic light-emitting diode device 23 includes an anode film layer 231, a light-emitting layer 232, and a cathode film layer 233 formed in sequence from a side close to the driving circuit backplane 10 to a side facing away from the driving circuit backplane 10. The anode film layer 231, the light-emitting layer 232, and the cathode film layer 233 are arranged on the pixel region 221, and the cathode film layer 233 covers both the pixel defining layer 22 and the pixel region 221 on a side of the pixel region 221 facing away from the second substrate 21. The bonding component 24 passes through the second substrate 21. One side of the bonding component 24 is connected to the anode film layer 231, and an other side of the bonding component 24 is bonded to the driving circuit layer. A gap D is provided between the second substrate 21 and the first substrate 11. In a first direction, a length of the second substrate 2121 in the first direction is less than a length of the first substrate 1111. A step surface 30 is defined on an end of the first substrate 11 close to an end of the second substrate 21, and the step surface 30 is communicated with the gap D. The encapsulation layer 40 is arranged at least on the first substrate 11, and extends to the gap to encapsulate the gap D between the first substrate 11 and the second substrate 21.

Thus, the first direction is a length direction of the display panel 100, and the driving circuit backplane 10 and the light-emitting unit carrier 20 are bonded through the bonding component 24, and the bonding component 24 passes through the second substrate 21. One side of the bonding component 24 is connected to the anode film layer 231, and an other side of the bonding component 24 is bonded to the driving circuit layer, to make the driving circuit layer and the anode film layer 231 be electrically connected. After the driving circuit backplane 10 and the light-emitting unit carrier 20 are bonded, a gap is defined between the second substrate 21 and the first substrate 11. The encapsulation layer 40 is arranged on the first substrate 11 and extends the encapsulation layer 40 to the gap, making the gap between the first substrate 11 and the second substrate 21 be encapsulated. Thus, the risk of water vapor intrusion can be reduced, thereby reducing the risk of corrosion failure inside the display panel 100.

In some embodiments, the first substrate 11 is a silicon-based substrate, and the silicon-based substrate can be configured as a single crystal silicon substrate. The driving circuit layer includes a plurality of active organic light emitting diode display devices made of complementary metal-oxide semiconductor (CMOS) devices as driving units. A protective layer is configured as an insulating organic protective layer and/or an inorganic protective layer. In some embodiments, the inorganic protective layer is configured as a SiO₂ layer.

In some embodiments, the second substrate 21 is a glass substrate, and the glass substrate can improve transmittance of the display panel 100 and increase brightness of the display panel 100. Holes for setting the bonding component 24 can be formed on the first substrate 11 by laser drilling, or can be formed on the first substrate 11 by exposure, development, and etching.

In some embodiments, the pixel defining layer 22 is made of an inorganic material. The inorganic material forms into a film through plasma enhanced chemical evaporation, and then the pixel region 221 is defined through a series of processes such as exposure, development, and etching.

In some embodiments, a material of the anode film layer 231, a material of the light-emitting layer 232, and a material of the cathode film layer 233 of the organic light-emitting diode device 23 are not specifically limited herein and can be selected according to the actual situation. During preparation, after the pixel region 221 is defined on the first substrate 11 through exposure, development, and etching, the material of the anode film layer 231 is first evaporated on the pixel region 221 to form the anode film layer 231, then material of the light-emitting layer 232 is evaporated to form the light-emitting layer 232, and finally, the material of the cathode film layer 233 is evaporated to form the cathode film layer 233.

In some embodiments, the anode film layer 231, the emitting layer, and the cathode film layer 233 can also be formed by evaporation at different evaporation angles during evaporation, so that the anode film layer 231, the emitting layer, and the cathode film layer 233 have different areas in the pixel region 221.

In some embodiments, the material of the cathode film layer 233 and the material of the light-emitting layer 232 are sequentially evaporated on the pixel region 221 to form the anode film layer 231 and the light-emitting layer 232. The material of the cathode film layer 233 continues to be evaporated on a side facing away from the anode film layer 231 and the light-emitting layer 232, thereby forming a continuous film structure on a surface of the pixel defining layer 22 to cover the pixel defining layer 22 and the pixel region 221.

In some embodiments, the bonding component 24 may be formed in a via by evaporation before forming the anode film layer 231, or after forming the anode film layer 231.

In some embodiments, the bonding component 24 protrudes towards the second substrate 21 on the first substrate 11 to facilitate bonding between the bonding component 24 and the driving circuit, resulting in a gap D between the second substrate 21 and the first substrate 11.

In some embodiments, referring to FIG. 1 to FIG. 4, the length of the second substrate 21 in the first direction is smaller than the length of the first substrate 11 to form the step surface 30. The step surface 30 communicates with the gap D. The step surface 30 is defined on the first substrate 11, and the encapsulation layer 40 is at least arranged on the first substrate 11, and the encapsulation layer 40 extends to the step surface 30 to encapsulate the gap D between the first substrate 11 and the second substrate 21. The step surface 30 can facilitate arrangement of a portion of the encapsulation layer 40, so that the encapsulation layer 40 can be fixed at the gap D, facilitating the encapsulation of the gap D.

In some embodiments, the gap D between the first substrate 11 and the second substrate 21 is a micro-gap. During long-term use of the display panel 100, the micro-gap D can lead to the ingress of water molecules into the interior of the display panel 100.

In some embodiments, a material of the encapsulation layer 40 may be glass adhesive. Since at least the first substrate 11 is the glass substrate, the encapsulation layer 40 made of the glass adhesive has a more compatible physical property with the glass substrate, enabling better encapsulation performance.

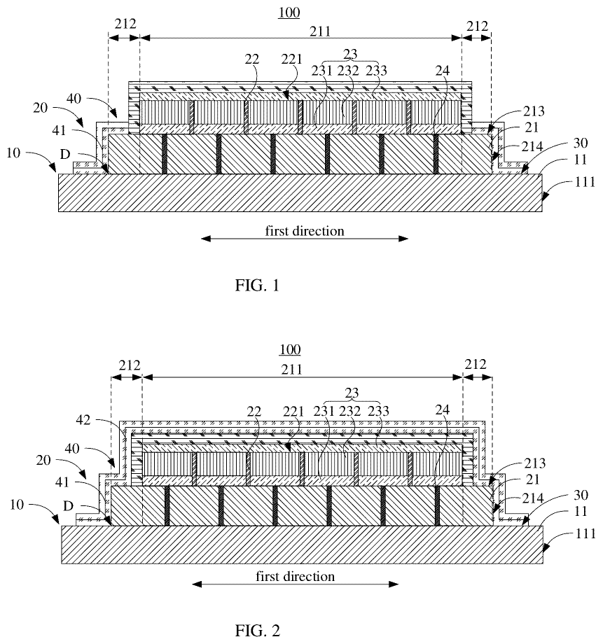

In some embodiments, referring to FIG. 1 or FIG. 2, the second substrate 21 defines a light-emitting region 211 and a non-light-emitting region 212. The light-emitting region 211 is provided with a plurality of organic light emitting diode devices 23, and the non-light-emitting region 212 is arranged radially outside the light-emitting region 211. A first plane 213 is defined on a side of the non-light-emitting region 212 facing away from the first substrate 11, and a second plane 214 is defined on a side of the non-light-emitting region 212 facing away from the light-emitting region 211. The first plane 213, the second plane 214, and the step surface 30 are successively connected. The encapsulation layer 40 includes a first packaging part 41, and the first packaging part 41 is arranged on the first plane 213, the second plane 214, and a portion of the step surface 30. The first packaging part 41 is configured to encapsulate the first plane 213, the second plane 214, and the portion of the step surface 30. Specifically, an extension length of the first packaging part 41 on the step surface 30 along the first direction may occupy one-third of the length of the step surface 30. Alternatively, the extension length of the first packaging part 41 along the first direction may be equal to the length of the step surface 30. The extension length of the first packaging part 41 on the step surface 30 can be selected according to the actual situation.

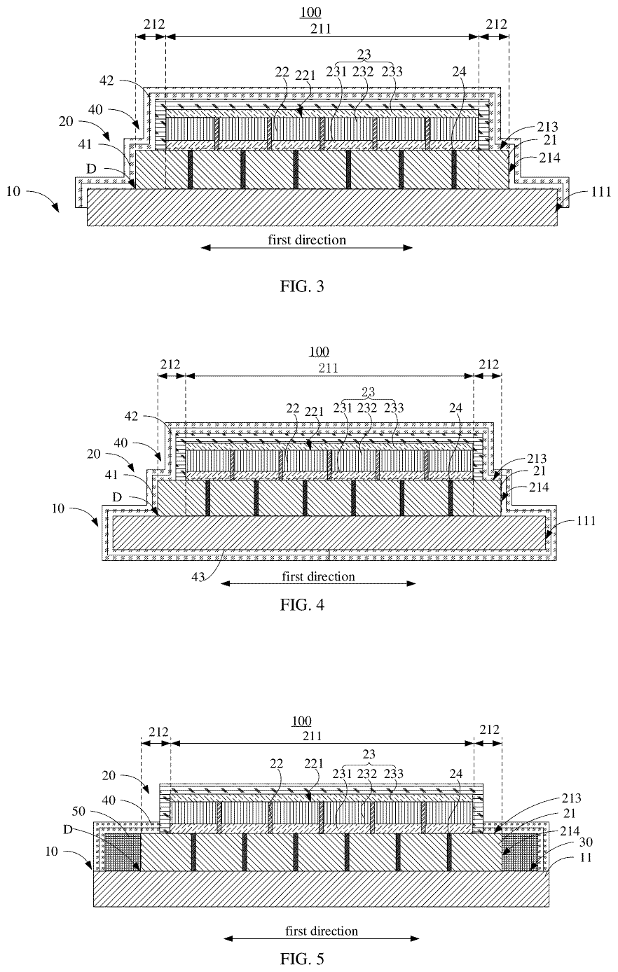

In some embodiments, referring to FIG. 3, a third plane 111 is defined on periphery of the first substrate 11. The second substrate 21 defines the light-emitting region 211 and the non-light-emitting region 212. The light-emitting region 211 has the plurality of organic light-emitting diode devices 23, and the non-light-emitting region 212 is arranged radially outside the light-emitting region 211. The first plane 213 is defined on a side of the non-light-emitting region 212 facing away from the first substrate 11, and the second plane 214 is defined on a side of the non-light-emitting region 212 facing away from the light-emitting region 211. The first plane 213, the second plane 214, the step surface 30, and the third plane 111 are successively connected. The encapsulation layer 40 includes the first packaging part 41, and the first packaging part 41 is arranged on the first plane 213, the second plane 214, the step surface 30, and the portion of the third plane 111. The first packaging part 41 is configured to encapsulate the first plane 213, the second plane 214, the step surface 30, and the portion of the third plane 111. Specifically, the extension length of the first packaging part 41 on the third plane 111 along a direction perpendicular to the first direction may occupy one-third of the length of the third plane 111. Alternatively, the extension length of the first packaging part 41 on the third plane 111 along the direction perpendicular to the first direction is equal to the length of the third plane 111. The extension length of the first packaging part 41 on the step surface 30 can be selected according to the actual situation.

In some embodiments, referring to FIG. 2 or FIG. 3, the encapsulation layer 40 further includes a second packaging part 42, and the second packaging part 42 is arranged on the light-emitting region 211. The second packaging part 42 is configured to encapsulate the plurality of organic light-emitting diode devices 23, and is connected to the first packaging part 41. The second packaging part 42 and the first packaging part 41 form an integrated structure. The integrated structure can also be called a monolithic structure, means the two components are made of a same material and the same process. The second packaging part 42 can provide additional encapsulation for the light-emitting region 211, thereby enhancing the sealing performance of the display panel 100.

In some embodiments, referring to FIG. 4, the encapsulation layer 40 further includes a third packaging part 43, and the third packaging part 43 is arranged outside the driving circuit backplane 10 and is configured to encapsulate the driving circuit backplane 10. The third packaging part 43 is connected to the first packaging part 41. The third packaging part 43 and the first packaging part 41 form an integrated structure. The third packaging part 43 can provide additional encapsulation for the light-emitting region 211, thereby enhancing the sealing performance of the display panel 100.

In some embodiments, referring to FIG. 1 to FIG. 4, the encapsulation layer 40 may further include the first packaging part 41, the second packaging part 42, and the third packaging part 43, and an encapsulation seam may be arranged on the third packaging part 43. The first packaging part 41, the second packaging part 42, and the third packaging part 43 can encapsulate the driving circuit backplane 10 and the light-emitting unit carrier 20 inside of the display panel 100, thereby achieving better encapsulation effect. The packaging process described in any one of the various embodiments can be selected to reduce risk of water vapor intrusion and ensure good reliability of the internal structure of the display panel 100.

In some embodiments, referring to FIG. 1 to FIG. 4, an organic encapsulation layer is arranged on the plurality of organic light-emitting diode devices 23, and can encapsulate the plurality of organic light-emitting diode devices 23. Alternatively, the organic encapsulation layer can also be configured as an inorganic encapsulation layer according to the actual situation.

In some embodiments, referring to FIG. 5 to FIG. 7, the display panel 100 further includes a drying component 50, and the drying component 50 is arranged on a side of the encapsulation layer 40 facing the light-emitting unit carrier 20. The drying component 50 is arranged on the step surface 30, and near the gap D. The drying component 50 can be a desiccant, capable of absorbing the water vapor in the event of water vapor ingress, thereby further reducing the risk of the water vapor intrusion through the gap D.

In some embodiments, referring to FIG. 5, the second substrate 21 defines the light-emitting region 211 and the non-light-emitting region 212. The light-emitting region 211 is provided with the plurality of organic light emitting diode devices 23, and the non-light-emitting region 212 is arranged radially outside the light-emitting region 211. The second plane 214 is defined on the side of the non-light-emitting region 212 facing away from the light-emitting region 211, and the drying component 50 is arranged on the step surface 30 and abuts against the second plane 214. Specifically, in a radial direction, the second plane 214 and the light-emitting region 211 are respectively arranged on opposite sides of the non-light-emitting region 212. The drying component 50 is configured to prevent the water vapor from entering the light-emitting region 211 and the driving circuit layer. When the water vapor intrudes, the water vapor is partially absorbed by the desiccant. The desiccant, combined with the encapsulation layer 40, can greatly reduce the risk of water vapor intrusion. Of course, based on the above desiccant design, any one of various packaging processes can be selected, which will not be elaborated here.

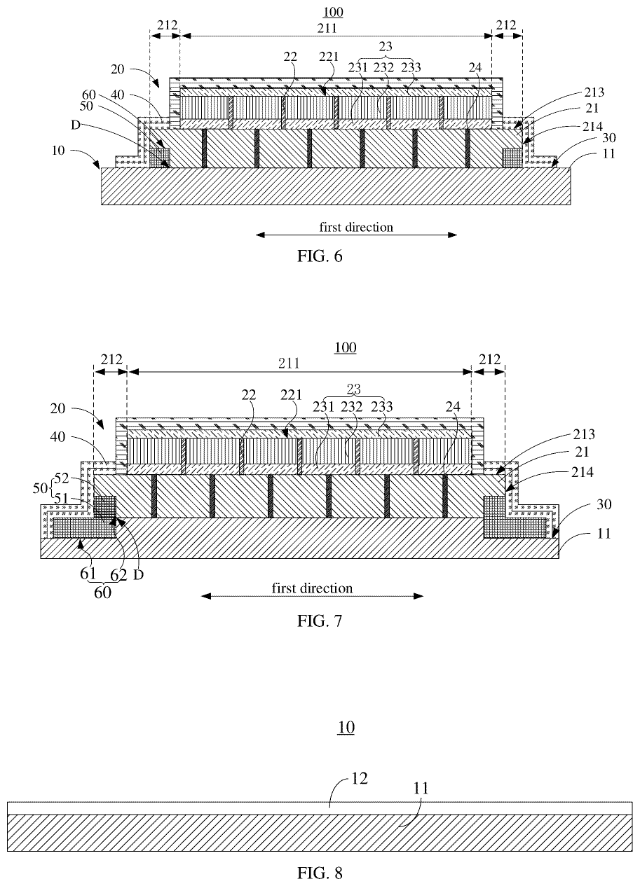

In some embodiments, referring to FIG. 6 and FIG. 7, the display panel 100 further includes the drying component 50, and the drying component 50 is arranged on the side of the encapsulation layer 40 facing the light-emitting unit carrier 20. An accommodation groove 60, communicating with the gap D, is defined on at least one of the first substrate 11 and the second substrate 21. An opening of the accommodation groove 60 faces the step surface 30, and the drying component 50 is provided in the accommodation groove 60. The accommodation groove 60 can be formed by a laser grooving process on a side of the second substrate 21 near the first substrate 11 in the non-light-emitting region 212. A ring-shaped groove structure is formed along a circumference direction of the second substrate 21. After bonding is completed, a groove structure is formed on circumference of the first substrate 11 and the second substrate 21. The groove structure is the accommodation groove 60 for receiving the drying component 50. Correspondingly, the drying component 50 also needs to be formed into a ring-shaped structure to fill the groove structure, which can greatly reduce the risk of water vapor intrusion. Of course, based on the above desiccant design, any one of various packaging processes can be selected, which will not be elaborated here.

In some embodiments, referring to FIG. 6, the second substrate 21 defines the light-emitting region 211 and the non-light-emitting region 212. The light-emitting region 211 is provided with the plurality of organic light-emitting diode devices 23, and the non-light-emitting region 212 is arranged radially outside the light-emitting region 211. The second plane 214 is defined on the side of the non-light-emitting region 212 facing away from the light-emitting region 211. The accommodation groove 60 is defined in the non-light-emitting region 212 of the second substrate 21, and the opening of the accommodation groove 60 faces the second plane 214. The drying component 50 is flush with the opening of the accommodation groove 60. This design allows the desiccant to be precisely filled in the accommodation groove 60, making the second plane 214 and a side of the desiccant lie on a same plane (of course, the “same plane” here refers to approximately the same plane), and also reducing the process difficulty when setting the encapsulation layer 40. Of course, based on the above desiccant design, any one of various packaging processes can be selected, which will not be elaborated here.

In some embodiments, referring to FIG. 7, the second substrate 21 defines a light-emitting region 211 and a non-light-emitting region 212. The light-emitting region 211 is provided with the plurality of organic light emitting diode devices 23, and the non-light-emitting region 212 is arranged radially outside the light-emitting region 211. The second plane 214 is defined on the side of the non-light-emitting region 212 facing away from the light-emitting region 211. The accommodation groove 60 includes a first accommodation groove 61 and a second accommodation groove 62. The first accommodation groove 61 is defined on a side of the non-light-emitting region 212 facing the first substrate 11, and the second accommodation groove 62 is defined on a side of the second substrate 21 facing the non-light-emitting region 212. The first accommodation groove 61 corresponds to the second accommodation groove 62. In some embodiments, the first accommodation groove 61 communicates with the second accommodation groove 62. The drying component 50 includes a first drying piece 51 and a second drying piece 52. The first drying piece 51 and the second drying piece 52 are integrated. In the first direction, a length of the first drying piece 51 is greater than a length of the second drying piece 52. In the first direction, the length of the first drying piece 51 is greater than a length of the first accommodation groove 61, and in the first direction, the length of the second drying piece 52 is equal to the length of the first accommodation groove 61. This design, on one hand, can increase a volume of the desiccant; on the other hand, a step surface, similar to the step surface 30 formed between the first substrate 11 and the second substrate 21, is also formed between the first drying piece 51 and the second drying piece 52 of the drying component 50; the second plane 214 and a side of the first drying piece 51 lie on a same plane, and a step surface is also formed to connect with the second plane 214; and when forming the encapsulation layer 40, the process difficulty of the encapsulation layer 40 can be reduced. Combining these two aspects, the display panel 100 achieves better water vapor resistance and further protects the display panel 100. Of course, based on the above desiccant design, any one of various packaging processes can be selected, which will not be elaborated here.

In the present disclosure, by arranging the encapsulation layer 40 on the display panel 100 and combining the first packaging part 41, the second packaging part 42, and the third packaging part 43, different encapsulation areas can be formed on the display panel 100. Arranging the drying component 50 on the step surface 30 can further prevent water vapor intrusion, and the drying component 50 can be equipped with various structures. In the process of preventing the water vapor intrusion, the diversification of processes has also been increased.

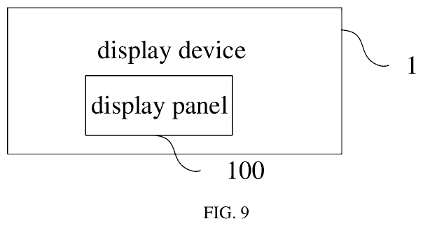

Referring to FIG. 9, the present disclosure also provides a display device 1 including any one of the display panels 100. The display device can include but is not limited to a mobile phone, a computer, etc. The mobile phone can be an ordinary phone, a feature phone, or a smartphone, etc. The smartphone can be a flat screen phone, a curved screen phone, or a foldable phone, etc. The display device is equipped with the display panel, and can be configured to display information on the device.

In the present disclosure, unless otherwise specified and limited, terms such as “arranged (provided)” and “connection” should be broadly understood, for example, they may refer to a fixed connection or a detachable connection, or an integration; a mechanical connection or an electrical connection; a direct connection or an indirect connection through an intermediate medium, as well as internal communication between two components or interaction relationships between two components. Those skilled in the art can understand the specific meanings of the above terms in this present disclosure according to specific circumstances.

In the description of this specification, references to the description of terms such as “some embodiments” herein means that specific features, structures, materials, or characteristics described the embodiments may be included in at least one embodiment of the present disclosure. In this specification, the schematic representation of the above terms does not necessarily refer to the same embodiment or example. Furthermore, the described specific features, structures, materials, or characteristics may be combined in any suitable manner in one or more embodiments or examples. Additionally, those skilled in the art can combine and integrate the different embodiments or examples described in this specification, as well as the features of different embodiments or examples, without conflicting with each other.

Although the embodiments of the present disclosure have been shown and described above, it can be understood that the above embodiments are exemplary and should not be construed as limiting the present disclosure. Those skilled in the art can make changes, modifications, substitutions, and variations to the above embodiments within the scope of the present disclosure. Therefore, any changes or modifications made in accordance with the claims and specification of the present disclosure should be within the scope of the present patent application.

1. A display panel, comprising:
a driving circuit backplane, comprising a first substrate and a driving circuit layer arranged on the first substrate;
a light-emitting unit carrier, comprising a second substrate, a pixel defining layer, an organic light emitting diode device, and a bonding component; wherein the pixel defining layer is arranged on the second substrate, and the pixel defining layer defines a pixel region; the organic light emitting diode device comprises an anode film layer, a light-emitting layer, and a cathode film layer formed in sequence from a side close to the driving circuit backplane to a side facing away from the driving circuit backplane; the anode film layer, the light-emitting layer, and the cathode film layer are arranged on the pixel region, and on a side of the pixel region facing away from the second substrate, the cathode film layer covers both the pixel defining layer and the pixel region; the bonding component passes through the second substrate, one side of the bonding component is electrically connected to the anode film layer, and an other side of the bonding component is bonded to the driving circuit layer;
a gap, defined between the second substrate and the first substrate, wherein a length of the second substrate is less than a length of the first substrate; an end of the first substrate is close to an end of the second substrate to define a step surface, and the step surface communicates with the gap; and
an encapsulation layer, arranged at least on the first substrate and extending to the step surface to encapsulate the gap between the first substrate and the second substrate.

2. The display panel as claimed in claim 1, wherein the second substrate defines a light-emitting region and a non-light-emitting region, the light-emitting region is provided with a plurality of the organic light emitting diode devices; the non-light-emitting region is arranged radially outside the light-emitting region, and a first plane is defined on a side of the non-light-emitting region facing away from the first substrate; a second plane is defined on a side of the non-light-emitting region facing away from the light-emitting region, and the first plane, the second plane, and the step surface are sequentially connected; and
the encapsulation layer comprises a first packaging part, and the first packaging part is arranged on the first plane, the second plane, and a portion of the step surface; and the first packaging part is configured to encapsulate the first plane, the second plane, and the portion of the step surface.

3. The display panel as claimed in claim 1, wherein a third plane is defined on periphery of the first substrate;
the second substrate defines a light-emitting region and a non-light-emitting region, the light-emitting region is provided with a plurality of the organic light emitting diode devices; the non-light-emitting region is arranged radially outside the light-emitting region, and a first plane is defined on a side of the non-light-emitting region facing away from the first substrate; a second plane is defined on a side of the non-light-emitting region facing away from the light-emitting region, and the first plane, the second plane, the step surface, and the third plane are sequentially connected; and
the encapsulation layer comprises a first packaging part, the first packaging part is arranged on the first plane, the second plane, the step surface, and a portion of the third plane; the first packaging part is configured to encapsulate the first plane, the second plane, the step surface, and the portion of the third plane.

4. The display panel as claimed in claim 2, wherein the encapsulation layer further comprises a second packaging part, the second packaging part is arranged on the light-emitting region; the second packaging part is configured to encapsulate the plurality of the organic light-emitting diode devices, and is connected to the first packaging part; and the second packaging part and the first packaging part are an integrated structure.

5. The display panel as claimed in claim 2, wherein the encapsulation layer further comprises a third packaging part, the third packaging part is arranged outside the driving circuit backplane, the third packaging part is configured for the driving circuit backplane, the third packaging part is connected to the first packaging part, and the third packaging part and the first packaging part are an integrated structure.

6. The display panel as claimed in claim 1, wherein the display panel further comprises a drying component, the drying component is arranged on a side of the encapsulation layer facing the light-emitting unit carrier, is arranged on the step surface, and is close to the gap.

7. The display panel as claimed in claim 6, wherein the second substrate defines a light-emitting region and a non-light-emitting region, the light-emitting region is provided with a plurality of the organic light emitting diode devices, the non-light-emitting region is arranged radially outside the light-emitting region, a second plane is defined on a side of the non-light-emitting region facing away from the light-emitting region, and the drying component is arranged on the step surface and abuts against the second plane.

8. The display panel as claimed in claim 1, wherein the display panel further comprises a drying component, the drying component is arranged on a side of the encapsulation layer facing the light-emitting unit carrier; an accommodation groove, communicating with the gap, is defined on at least one of the first substrate and the second substrate; an opening of the accommodation groove faces the step surface, and the drying component is arranged in the accommodation groove.

9. The display panel as claimed in claim 8, wherein the second substrate defines a light-emitting region and a non-light-emitting region, the light-emitting region is provided with a plurality of the organic light emitting diode devices, the non-light-emitting region is arranged radially outside the light-emitting region, a second plane is defined on a side of the non-light-emitting region facing away from the light-emitting region, the accommodation groove is defined in the non-light-emitting region of the second substrate, the opening of the accommodation groove faces the second plane, and the drying component is flush with the opening of the accommodation groove.

10. The display panel as claimed in claim 8, wherein the second substrate defines a light-emitting region and a non-light-emitting region, the light-emitting region is provided with a plurality of the organic light emitting diode devices, the non-light-emitting region is arranged radially outside the light-emitting region, and a second plane is defined on a side of the non-light-emitting region facing away from the light-emitting region;
the accommodation groove comprises a first accommodation groove and a second accommodation groove; the first accommodation groove is defined on a side of the non-light-emitting region facing the first substrate, and the second accommodation groove is defined on a side of the second substrate facing the non-light-emitting region; and the first accommodation groove communicates with the second accommodation groove; and
the drying component comprises a first drying piece and a second drying piece, the first drying piece and the second drying piece are an integrated structure; in the first direction, a length of the first drying piece is greater than a length of the second drying piece; in the first direction, the length of the first drying piece is greater than a length of the first accommodation groove; in the first direction, the length of the second drying piece is equal to the length of the first accommodation groove.

11. A display panel, comprising:
a driving circuit backplane, comprising a first substrate and a driving circuit layer arranged on the first substrate;
a light-emitting unit carrier, comprising a second substrate, a pixel defining layer, an organic light emitting diode device, and a bonding component; wherein the pixel defining layer is arranged on the second substrate, and the pixel defining layer defines a pixel region; the organic light emitting diode device comprises an anode film layer, a light-emitting layer, and a cathode film layer formed in sequence from a side close to the driving circuit backplane to a side facing away from the driving circuit backplane; the anode film layer, the light-emitting layer, and the cathode film layer are arranged on the pixel region, and on a side of the pixel region facing away from the second substrate, the cathode film layer covers both the pixel defining layer and the pixel region; the bonding component passes through the second substrate, one side of the bonding component is electrically connected to the anode film layer, and an other side of the bonding component is bonded to the driving circuit layer;
a gap, between the second substrate and the first substrate, wherein a length of the second substrate is less than a length of the first substrate; an end of the first substrate is close to an end of the second substrate to define a step surface, and the step surface communicates with the gap; and
a drying component, wherein the drying component is arranged on the step surface, and is close to the gap; or an accommodation groove, communicating with the gap, is defined on at least one of the first substrate and the second substrate; an opening of the accommodation groove faces the step surface, and the drying component is arranged in the accommodation groove.

12. A display device, comprising a display panel, comprising:
display panel, comprising:
a driving circuit backplane, comprising a first substrate and a driving circuit layer arranged on the first substrate;
a light-emitting unit carrier, comprising a second substrate, a pixel defining layer, an organic light emitting diode device, and a bonding component; wherein the pixel defining layer is arranged on the second substrate, and the pixel defining layer defines a pixel region; the organic light emitting diode device comprises an anode film layer, a light-emitting layer, and a cathode film layer formed in sequence from a side close to the driving circuit backplane to a side facing away from the driving circuit backplane; the anode film layer, the light-emitting layer, and the cathode film layer are arranged on the pixel region, and on a side of the pixel region facing away from the second substrate, the cathode film layer covers both the pixel defining layer and the pixel region; the bonding component passes through the second substrate, one side of the bonding component is electrically connected to the anode film layer, and an other side of the bonding component is bonded to the driving circuit layer;
a gap, between the second substrate and the first substrate, wherein a length of the second substrate is less than a length of the first substrate; an end of the first substrate is close to an end of the second substrate to define a step surface, and the step surface communicates with the gap; and
an encapsulation layer, arranged at least on the first substrate and extending to the step surface to encapsulate the gap between the first substrate and the second substrate.

13. The display device as claimed in claim 12, wherein the second substrate defines a light-emitting region and a non-light-emitting region, the light-emitting region is provided with a plurality of the organic light emitting diode devices; the non-light-emitting region is arranged radially outside the light-emitting region, and a first plane is defined on a side of the non-light-emitting region facing away from the first substrate; a second plane is defined on a side of the non-light-emitting region facing away from the light-emitting region, and the first plane, the second plane, and the step surface are sequentially connected; and
the encapsulation layer comprises a first packaging part, and the first packaging part is arranged on the first plane, the second plane, and a portion of the step surface; and the first packaging part is configured to encapsulate the first plane, the second plane, and the portion of the step surface.

14. The display device as claimed in claim 12, wherein a third plane is defined on periphery of the first substrate;
the second substrate defines a light-emitting region and a non-light-emitting region, the light-emitting region is provided with a plurality of the organic light emitting diode devices; the non-light-emitting region is arranged radially outside the light-emitting region, and a first plane is defined on a side of the non-light-emitting region facing away from the first substrate; a second plane is defined on a side of the non-light-emitting region facing away from the light-emitting region, and the first plane, the second plane, the step surface, and the third plane are sequentially connected; and
the encapsulation layer comprises a first packaging part, the first packaging part is arranged on the first plane, the second plane, the step surface, and a portion of the third plane; the first packaging part is configured to encapsulate the first plane, the second plane, the step surface, and the portion of the third plane.

15. The display device as claimed in claim 13, wherein the encapsulation layer further comprises a second packaging part, the second packaging part is arranged on the light-emitting region; the second packaging part is configured to encapsulate the plurality of the organic light-emitting diode devices, and is connected to the first packaging part; and the second packaging part and the first packaging part are an integrated structure.

16. The display device as claimed in claim 13, wherein the encapsulation layer further comprises a third packaging part, the third packaging part is arranged outside the driving circuit backplane, the third packaging part is configured for the driving circuit backplane, the third packaging part is connected to the first packaging part, and the third packaging part and the first packaging part are an integrated structure.

17. The display device as claimed in claim 12, wherein the display panel further comprises a drying component, the drying component is arranged on a side of the encapsulation layer facing the light-emitting unit carrier, is arranged on the step surface, and is close to the gap.

18. The display device as claimed in claim 17, wherein the second substrate defines a light-emitting region and a non-light-emitting region, the light-emitting region is provided with a plurality of the organic light emitting diode devices, the non-light-emitting region is arranged radially outside the light-emitting region, a second plane is defined on a side of the non-light-emitting region facing away from the light-emitting region, and the drying component is arranged on the step surface and abuts against the second plane.

19. The display device as claimed in claim 12, wherein the display panel further comprises a drying component, the drying component is arranged on a side of the encapsulation layer facing the light-emitting unit carrier; an accommodation groove, communicating with the gap, is defined on at least one of the first substrate and the second substrate; an opening of the accommodation groove faces the step surface, and the drying component is arranged in the accommodation groove.

20. The display device as claimed in claim 19, wherein the second substrate defines a light-emitting region and a non-light-emitting region, the light-emitting region is provided with a plurality of the organic light emitting diode devices, the non-light-emitting region is arranged radially outside the light-emitting region, a second plane is defined on a side of the non-light-emitting region facing away from the light-emitting region, the accommodation groove is defined in the non-light-emitting region of the second substrate, the opening of the accommodation groove faces the second plane, and the drying component is flush with the opening of the accommodation groove.
